(19) United States
(12) Patent Application Publication
(10) Pub. No.: US 2024/0343945 A1
(43) Pub. Date: Oct. 17, 2024

(54) CURABLE HOT MELT SILICONE COMPOSITION, CURED PRODUCT OF SAID COMPOSITION, AND METHOD FOR PRODUCING FILM OR THE LIKE COMPRISING SAID COMPOSITION

(71) Applicant: DOW TORAY CO., LTD., Shinagawa-Ku, Tokyo (JP)

(72) Inventors: Yuki YOKOUCHI, Ichihara-shi, Chiba (JP); Tomohiro IIMURA, Ichihara-shi, Chiba (JP); Haruhiko FURUKAWA, Ichihara-shi, Chiba (JP)

(21) Appl. No.: 18/294,235

(22) PCT Filed: Jul. 29, 2022
(86) PCT No.: PCT/JP2022/029267

§ 371 Date: Feb. 1, 2024

(30) Foreign Application Priority Data
Aug. 12, 2021 (JP) 2021-131772

(51) Int. Cl. C09J 7/35; C09J 5/06; C09J 7/10

(52) U.S. Cl. CPC C09J 7/35; C09J 5/06; C09J 7/10; C09J 2203/326; C09J 2301/304; C09J 2301/416; C09J 2483/00

(57) ABSTRACT

Provided is a hot-melt type silicone composition that can be cured at a wide range of temperatures from low to high depending on the sealing process and the heat resistance of the resin members, in particular, that can realize good curability even at low temperatures such as room temperature, that imparts excellent transparency and resistance to yellowing to the resulting cured product, and that has excellent workability and handling in, e.g., overmolding. The curable hot-melt silicone composition comprises: (A) a resin-linear structure-containing organopolysiloxane block copolymer having a resinous organosiloxane block X containing a triorganosiloxane unit (M^{RA} unit) having silicon atom-bound functional group (R^{A}) containing an acrylic group or a methacrylic group, and a Q unit, and a chain organosiloxane block Y, and having at least two of the R^{A} groups in the molecule; and (B) a radical polymerization initiator. Also provided are uses of the hot-melt type silicone composition.

### TECHNICAL FIELD

The present invention relates to a curable hot-melt silicone composition and a sealing technique for an optical member using the composition.

### BACKGROUND ART

Curable silicone compositions are utilized in a wide range of industrial fields because they are cured to form cured products having excellent heat resistance, cold resistance, electrical insulation, weather resistance, water repellency, and transparency. The cured product of such a curable silicone composition is also suitable as a sealing agent for optical materials and semiconductor devices because it is hardly discolored as compared with other organic materials, and physical properties are less deteriorated.

The present patent applicants have disclosed, for example, heat curable hot-melt silicone compositions in Patent Document 1 and Patent Document 2. Specifically, Patent Document 1 discloses a heat curable composition containing a hot-melt silicone having a hydrosilylation reactive group and/or a radical reactive group, and Patent Document 2 discloses a reactive silicone composition that is curable by a hydrosilylation reaction, has an alkenyl group, and provides a reactive thermoplastic material that flows at high temperatures. However, these documents do not specifically disclose a hot-melt silicone composition containing a resin-linear structure containing an organopolysiloxane block copolymer having a resinous organosiloxane block having an acrylic group or a methacrylic group, and the curing agent disclosed in Patent Document 1 or 2 is a hydrosilylation reaction catalyst or an organic peroxide for a thermal curing reaction requiring a high temperature exceeding 150° C. A curing reaction or a photocuring reaction at a low temperature is neither mentioned nor described.

However, demand has increased in recent years for optical devices and optical semiconductor devices using resin members with low heat resistance due to demand for a reduction in weight and an increase in functionality. However, as mentioned above, conventional hot-melt silicone compositions have high curing temperatures that can be practicable in sealing processes, etc., which may cause deformation and degradation of organic resins with low heat resistance.

Meanwhile, in order to respond to the demand for low temperature curing, the present patent applicants have proposed in Patent Document 3 (unpublished at the time of filing) a curable hot-melt silicone composition that contains an organopolysiloxane resin having a hydrosilylation reaction curing reactivity functional group such as a vinyl group and a UV active type hydrosilylation reaction catalyst and that is curable at a low temperature below 100° C. However, when optimizing the composition by reducing the amount of curing retardant used, a high temperature curing at around 120° C. may be required after catalyst activation by high energy beam irradiation due to the relationship between curing speed and industrial productivity associated with the sealing process, and there is still room for improvement in the rapid curing process at room temperature/low temperatures for organic resins with low heat resistance. Note that there is no description or suggestion in Patent Document 3 of any curing agent other than the use of resin-linear structure-containing organopolysiloxane block copolymers with acrylic or methacrylic groups and a hydrosilylation reaction catalyst.

In contrast, active energy beam curable hot-melt silicone compositions that use thiol-ene reactions have been proposed in Patent Document 4, etc. Although these products have excellent rapid curability at room temperature (or low temperatures), they have low resistance to yellowing of cured products and are difficult to apply in applications where transparency is required.

### RELATED ART DOCUMENTS

### Patent Documents

Patent Document 1: International Unexamined Patent Application Publication No. (WO) 2016/136243
Patent Document 2: Japanese Unexamined Patent Application Publication No. 2014-009322
Patent Document 3: International Patent Application PCT/JP2021/12840 (unpublished at the time of filing)
Patent Document 4: International Unexamined Patent Application Publication No. (WO) 2017/068762

### SUMMARY OF THE INVENTION

### Problem to be Solved by the Invention

It is an object of the present invention to provide a hot-melt type silicone composition that can be cured at a wide range of temperatures from low to high depending on the sealing process and the heat resistance of the resin members, in particular, that can realize good curability even at low temperatures such as room temperature, that imparts excellent physical strength such as durability, as well as transparency and resistance to yellowing, to the resulting cured product, and that has excellent workability and handling in, for example, overmolding; and to provide a use of such composition.

### Means for Solving the Problem

As a result of extensive research, the present inventors discovered that the problem stated above could be solved by a curable hot-melt silicone composition comprising a resin-linear structure-containing organopolysiloxane block copolymer having a resinous organosiloxane block X with an acrylic or methacrylic group, which is a silicon atom-bound functional group (R^{A}) and a chain organosiloxane block Y consisting of a diorganosiloxane unit, there being at least two R^{A} groups in the molecule, and (B) a radical polymerization initiator. The present invention is a product of this discovery. This composition has excellent hot-melt properties, and depending on the choice of radical polymerization initiator, can realize heat curing at high temperatures or curing at room temperature to low temperature by irradiation with high energy beams, and has the advantage of imparting excellent durability, transparency, and resistance to yellowing with respect to UV light and high heat and humidity conditions, etc. to the resulting cured product.

Specifically, the curable hot-melt silicone composition of the present invention comprises: (A) 100 parts by mass of a resin-linear structure-containing organopolysiloxane block copolymer having a siloxane unit (M^{RA} unit) represented by R^{A}ₐR^{B}₍₃₋ₐ₎SiO_{1/2} (where R^{A} is a silicon atom-bound functional group containing acrylic or methacrylic groups, R^{B} is a monovalent organic group excluding R^{A}, and a is a number in the range 1 to 3), a resinous organosiloxane block X containing a siloxane unit (Q unit) represented by SiO_{4/2} and having an acrylic group or methacrylic group, a chain organosiloxane block Y having a siloxane unit represented by {R^{C}₂SiO_{2/2}}_{β} (where R^{C} is a monovalent organic group and p is 2 or more), and having at least two silicon atom-bound functional groups (R^{A}) above in the molecule; and (B) 0.1 to 10 parts by mass of a radical polymerization initiator. Component (B) may be a photo-radical polymerization initiator, thermal radical polymerization initiator, or a combination thereof, and the type of component (B), the curing method, and the curing temperature may be selected according to the sealing process using the hot-melt silicone composition and the heat resistance of the object to be sealed.

In particular, when at least some of component (B) is a photo-radical polymerization initiator (B1), it is possible to realize an active energy beam curable hot-melt silicone composition with good curability at room temperature because of its photo-curing properties when irradiated with a high energy beam.

In addition, the problem stated above can be suitably solved by the curable hot-melt silicone composition formed into a sheet or film, a peelable laminate containing the same, and a production method therefor. Similarly, the problem stated above can be suitably solved by a cured product obtained by curing the curable hot-melt silicone composition according to the present invention, a semiconductor device or an optical semiconductor device comprising the cured product, and a sealing method therefor.

### Effect of the Invention

The curable silicone composition of the present invention has good hot-melt properties and can be cured in a wide temperature range from a low temperature such as room temperature to high temperature by heat curing at high temperature and/or irradiation with high energy beams such as ultraviolet light depending on the sealing process and the heat resistance of the resin member. In particular, the curable silicone composition can realize good curability even at low temperatures such as room temperature, that imparts excellent physical strength such as durability, as well as transparency and resistance to yellowing, to the resulting cured product, and that has excellent workability and handling in, for example, overmolding. Therefore, it can be suitably used in various sealing processes and substrate materials, especially as a sealing agent to protect resin substrates with low heat resistance, through the selection of curing system.

Also, the present invention can provide such a curable hot-melt silicone composition in the form of a sheet or film with a thickness of 10 to 1000 μm without voids, etc., or in the form of a releasable laminate containing such a curable silicone composition sheet or film as well as a release sheet or film. In addition, a sheet or film comprising the curable silicone composition of the present invention, or a peelable laminate containing this sheet or film, can be cut to a desired size as needed in the manufacturing process of electronic components, for example, a semiconductor device, and can be applied to industrial production processes such as batch sealing or batch bonding to large area base materials, and in particular, through the selection of curing agents and curing systems, a good sealing process can be realized at low temperatures, such as room temperature, by high energy beam irradiation.

### DESCRIPTION OF THE PREFERRED EMBODIMENTS

Embodiments of the present invention will be described below in detail. The present invention is not limited by the following embodiments, and various types of modifications may be made within the scope of the gist of the present invention.

In the present specification, room temperature means the temperature of an environment where the curable silicone composition of the present invention is handled. Room temperature typically refers to 0° C. to 40° C., particularly refers to 15 to 30° C., and more particularly refers to 18° C. to 25° C.

In the present invention, unless otherwise stated, “having hot-melt properties” means the softening point of a composition is between 5° and 200° C., and the composition has a melt viscosity at 150° C. (preferably, melt viscosity of less than 1000 Pa·s) and has flowable properties. Therefore, in the present specification, a curable silicone composition having hot-melt properties of the present invention is also referred to as a curable hot-melt silicone composition. In particular, the melt viscosity of the curable hot-melt silicone composition in the present invention has a complex viscosity of more than 10,000 Pa·s for the pre-cured composition at 25° C., or is solid and has no flowability, and has a complex viscosity of less than 10,000 Pa·s for the pre-cured composition at 80° C., preferably a complex viscosity in the range of 100 to 10,000 Pa s at 80° C., and more preferably a complex viscosity of 200 to 9,000 Pa·s for the pre-cured composition at 80° C. However, this is more preferable from the standpoint of the sealing process for semiconductors and other devices that use this composition. In particular, when the complex viscosity for the pre-curing composition at 80° C. is within the above range, the composition has excellent low-temperature fluidity, and therefore, conferring an advantage that the composition can till and be molded at the sealing site even on a base material with low heat resistance at a relatively low temperature.

In the present invention, the complex viscosity at a certain temperature refers to the complex viscosity measured in a range of 25° C. to 100° C. using a complex viscometer such as MCR302 manufactured by Anton Paar GmbH and recorded at a specific temperature.

### [Curable Hot Melt Silicone Composition]

The curable hot-melt silicone composition of the present invention may contain:
(A) 100 parts by mass of a resin-linear structure-containing organopolysiloxane block copolymer having a siloxane unit (M^{RA} unit) represented by R^{A}ₐR^{B}₍₃₋ₐ₎SiO_{1/2} (where R^{A} is a silicon atom-bound functional group containing acrylic or methacrylic groups, R^{B} is a monovalent organic group excluding R^{A}, and a is a number in the range of 1 to 3), a resinous organosiloxane block X containing a siloxane unit (Q unit) represented by SiO_{4/2} and having an acrylic group or methacrylic group, a chain organosiloxane block Y having a siloxane unit represented by {R^{C}₂SiO_{2/2}}_{β} (where R^{C} is a monovalent organic group and p is 2 or more), and having at least two silicon atom-bound functional groups (R^{A}) described above in the molecule; (B) 0.1 to 10 parts by mass of a radical polymerization initiator; and optionally (C) an organopolysiloxane resin containing, in the molecule, an M unit and a Q unit, represented by R^{B}₃SiO_{1/2} and R^{A}ₐR^{B}₍₃₋ₐ₎SiO_{1/2} (where a represents an integer from 1 to 3 and each R^{B} independently represents a monovalent organic group excluding R^{A}), the ratio of the amount of substance of M unit per Q unit being in a range of 0.5 to 2.0; (D) an organopolysiloxane resin containing, in the molecule, an M unit and a Q unit, represented by R^{B}₃SiO_{1/2} (where each R independently represents a monovalent organic group excluding R^{A}), the ratio of the amount of substance of M unit to Q unit being in a range of 0.5 to 2.0; (E) a polydimethylsiloxane optionally having an alkenyl group; (F) an organic solvent; and (G) a known adhesion-imparting agent. In addition, the curable hot-melt silicone composition of the present invention may contain other additives known in the art (for example, heat resistance additives) to the extent that the properties targeted by the present invention are maintained. When at least some component (B) is a photo-radical polymerization initiator (B1), the composition may and preferably should be used with a photosensitizer (B′).

Because the composition contains component (A) above, it has curability derived from the radical polymerizable group and is a low-fluidity or non-fluid solid at room temperature, but has hot-melt properties and becomes fluid when heated. The product is extremely useful in the sealing process for semiconductors, etc., because it fills voids in the base material, etc., without excess or deficiency, and cures quickly by irradiation or heating with high-energy rays, enabling sealing with the cured product while the internal stress is sufficiently low, making it extremely useful in the sealing process for semiconductors, etc.

Note that the shape of the curable hot-melt silicone composition of the present invention is not particularly limited, and may be, for example, in a form molded into a sheet or film, with the sheet or film form being particularly preferred. Components and optional components included in the composition of the present invention will be described below.

### [Component (A)]

Component (A) is the main component of the present composition and is a resin-linear structure-containing organopolysiloxane block copolymer having a resin-like organosiloxane block X having a silicon-bonded functional group containing an acrylic or methacrylic group and a chain organosiloxane block Y and contains at least two of the acrylic or methacrylic groups in the molecule. Such (A) component gives the composition as a whole sufficient hot-melt properties for practical use, including good flowability (melt viscosity) at about 80° C. Since it has specific radical polymerizable groups in the molecule, good curability can be achieved in a wide temperature range from low to high, such as room temperature, by selecting a radical polymerization initiator (B) and a curing system.

More specifically, the component (A) is a resin-linear structure-containing organopolysiloxane block copolymer having a resinous organosiloxane block X containing a siloxane unit (M^{RA} unit) represented by R^{A}ₐR^{B}₍₃₋ₐ₎SiO_{1/2} (where R^{A} is a silicon atom-bound functional group containing acrylic or methacrylic groups, R^{B} is a monovalent organic group excluding R^{A}, and a is a number in the range of 1 to 3), and a siloxane unit (Q unit) represented by SiO_{4/2} and having an acrylic group or methacrylic group, and a chain organosiloxane block Y having a siloxane unit represented by {R^{C}₂SiO_{2/2}}_{β} (where R^{C} is a monovalent organic group and @ is 2 or more), and having at least two silicon atom-bound functional groups (R^{A}) above in the molecule. In order to give the composition as a whole a practically suitable melt viscosity (specifically, a range in which the complex viscosity of the pre-cured composition at 80° C. is less than 10,000 Pa s), it is preferable that the molar ratio (mass ratio) of the resinous organosiloxane block X and chain organosiloxane block Y, comprising component (A) be in the range 1:99 to 80:20, and more preferably in the range 20:80 to 60:40. Block copolymers in which these organosiloxane blocks (X and Y) meet the above molar ratios can be obtained by conducting a synthesis reaction by preparing the raw materials described below that give the X or Y blocks at the above-described molar ratios.

The component (A) is preferably a resin-linear structure-containing organopolysiloxane block copolymer having a structure in which resin-like organosiloxane block X and a chain organosiloxane block Y are linked by a siloxane bond or a silalkylene bond between silicon atoms constituting the blocks, and the above-mentioned linking group can be introduced between the blocks by condensation reaction or hydrosilylation reaction of the below-mentioned raw materials which give the X or Y block. Suitably, the structure of block X and block Y linked by siloxane bonds between silicon atoms is especially preferred from the standpoint of hot-melt properties.

Component (A) contains, in the resinous organosiloxane block X, a siloxane unit (M^{RA} unit) having silicon-bonded functional groups containing acrylic or methacrylic groups (R^{A}) and a siloxane unit represented by SiO_{4/2} (Q unit), and may further contain a siloxane unit (M unit) represented by R^{B}₃SiO_{1/2} (where R^{B} is a monovalent organic group other than R^{A}). From the standpoint of the hot-melt properties of component (A) as a whole, the sum of the amount of substance of M and M^{RA} units per mole of Q units in the resinous organosiloxane block X is preferably in the range of 0.5 to 2.0 moles, and more preferably in the range of 0.5 to 1.50 moles. The resinous organosiloxane block X may further contain a small amount of a siloxane unit (T unit) represented by RSiO_{3/2} (where R is a monovalent organic group which may contain R^{A}) or R₂SiO_{2/2} (where R is the same monovalent organic group described above), but the sum of the amounts of T units and D units per mole of Q unit is preferably less than 0.1 mole. The mass ratio (=molar ratio) of each siloxane unit in the resinous organosiloxane block X or MQ-type organopolysiloxane resin that provides block X can be easily measured by ²⁹Si nuclear magnetic resonance. This is also true for components other than component (A).

Component (A) has radical polymerization reactivity derived from the siloxane unit (M^{RA} unit) in resinous organosiloxane block X, particularly high energy beam curability at low temperatures. In particular, in order to realize a curing reaction, in addition to having at least two, preferably three or more silicon-bonded functional groups (R^{A}) containing an acrylic group or a methacrylic group in the molecule, the amount of substance of the M^{RA} unit relative per mole of Q unit in the resinous organosiloxane block X is preferably in the range of 0.02 to 0.50 mol, and more preferably in the range of 0.02 to 0.40 mol.

The silicon-bonded functional group R^{A} in component (A) is not particularly limited as long as it has an acrylic group or a methacrylic group in the molecule, and an acrylic group or a methacrylic group bonded to a silicon atom constituting the M^{RA} unit directly or via a divalent or higher functional group can be used. The reaction for introducing the functional group R^{A} having an acrylic group or a methacrylic group into the resinous organosiloxane may be carried out by any reaction, and may be carried out before or after the linking reaction of both blocks described later.

More specifically, R^{A} is expressed by the following general formula.

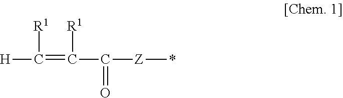

In the formula, R¹ mutually independently represents a hydrogen atom, a methyl group, or a phenyl group, and preferably a hydrogen atom or a methyl group in order to form an acrylic group or a methacrylic group moiety. Z represents a divalent organic group which may contain a hetero atom and is bonded to a silicon atom constituting the main chain of the polysiloxane represented by *, and may be a divalent organic group optionally containing an oxygen atom, a nitrogen atom or a sulfur atom.

Here, Z is preferably any one kind of group selected from an alkylene group having from 2 to 22 carbon atoms,
a divalent organic group represented by —R³—C(═O)—O—R⁴— {where R³ is an alkylene group having 2 to 22 carbon atoms, and R⁴ is a group selected from an ethylene group, a propylene group, a methylethylene group and a hexylene group},
a divalent organic group represented by —Z¹—X—C(═O)—X—Z²— {where Z¹ is —O(CH₂)ₖ— (k being a number in the range of 0 to 3), and X represents an oxygen atom, a nitrogen atom, or a sulfur atom. Z² represents a divalent organic group expressed by —[(CH₂)₂O]ₘ(CₙH₂ₙ)— (where m is a number in a range 0 to 3, n is a number in a range 2 to 10) bonded to a silicon atom constituting the main chain of the polysiloxane represented by *}, and a divalent linking group represented by —Z¹—R²₂Si—O—R²₂Si—Z²— described below.

Particularly preferably, the silicon-bonded functional group (R^{A}) is expressed by general formula (1):

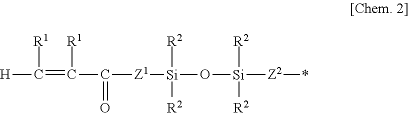

In the formula, R¹ mutually independently represents a hydrogen atom, a methyl group, or a phenyl group, and preferably a hydrogen atom or a methyl group. R² mutually independently represents an alkyl group or an aryl group, preferably an alkyl group or a phenyl group having 1 to 20 carbon atoms for industrial purposes, and particularly preferably a methyl group. Z¹ represents —O(CH₂)ₘ— (where m is a number in the range of 0 to 3), and m is preferably 1 or 2. Z² represents a divalent organic group expressed by —CₙH₂ₙ— (where n is a number in a range of 2 to 10) bonded to a silicon atom constituting the main chain of the polysiloxane represented by *, and n is preferably 2 to 6 for practical use. Note that the silicon-bonded functional group (R^{A}) expressed by general formula (1) can be introduced into a molecule by reacting a silicon-bonded functional group containing at least one alkenyl group (R^{Alk}) and a hydrosilane compound having a silicon-bonded hydrogen atom and (meth)acrylic functional group in a molecule (for example, 3-(1,1,3,3-tetramethyldisiloxanyl)propyl methacrylate) in the presence of a hydrosilylation reaction catalyst. Furthermore, the same reaction may be and preferably is performed in the presence of a polymerization inhibitor such as dibutylhydroxytoluene (BHT).

In component (A), R^{B}, which is a monovalent organic group other than R^{A}, may include: alkyl groups such as methyl, ethyl, propyl, butyl, pentyl, hexyl, and heptyl; aryl groups such as phenyl, tolyl, xylyl, and naphthyl; aralkyl groups such as benzyl and phenethyl; alkyl halide groups such as chloromethyl, 3-chloropropyl, and 3,3,3-trifluoropropyl; and alkenyl groups such as vinyl, allyl, butenyl, pentenyl, and hexenyl. From an industrial standpoint, one or more of the following groups is especially preferred: methyl, phenyl, vinyl, and hexenyl groups. At least some of the R^{B}s may and should be alkenyl groups with 2 to 12 carbon atoms.

The resinous organosiloxane block X in the component (A) may contain, in addition to the M^{R}A unit, a siloxane unit (M^{Alk} unit) represented by R^{B(Alk)}₃SiO_{1/2} (where R^{B(Alk)} is an alkenyl group having 2 to 12 carbon atoms) as some of the M units. Such an M^{Alk} unit may be functional groups that remain as unreacted alkenyl groups in the resinous organosiloxane block X when R^{A} is introduced by a hydrosilylation reaction to silicon atom-bound functional groups containing at least one alkenyl group. Like functional group R^{A}, the alkenyl group in component (A) is reactive for radical polymerization and is capable of undergoing a radical polymerization reaction in the presence of the component (B). Another curing reaction may also be introduced to realize a dual curing system. The amount of M^{Alk} unit in the resinous organosiloxane block X is preferably in the range of 0.01 to 0.25 mol, and more preferably in the range of 0.05 to 0.10 mol per mole of Q unit.

The chain organosiloxane block Y in component (A) has a chain siloxane structure represented by {R^{C}₂SiO_{2/2}}_{β} composed of diorganosiloxane units represented by R^{C}₂SiO_{2/2}. Here, R^{c} is a monovalent organic group, and may be one or more functional groups selected from functional groups R^{A} and R^{B}, which is a monovalent organic group other than R^{A}, and industrially, it is particularly preferable to include one or more of a methyl group, a phenyl group, a vinyl group and a hexenyl group from an industrial standpoint. β is a number equal to or greater than 2, but is preferably a number in the range of 5 to 5000 and more preferably a number in the range of 10 to 2000 because it is desirable from the standpoint of hot-melt properties that a linear molecular structure composed of polydiorganosiloxane with a certain chain length is included in the molecule.

Such (A) component is obtained by linking an MQ-type organopolysiloxane resin, which contains siloxane units represented by R′SiO_{1/2} and SiO_{4/2} and may optionally contain hydroxyl groups or other siloxane units, with a chain organopolysiloxane having reactive functional groups at the ends of the molecular chain and a chain siloxane structure represented by {R^{C}₂SiO_{2/2}}_{β}. Here, R′ is a monovalent organic group, and a group similar to the one or more functional groups chosen from functional groups R^{A} and R^{B}, which is a monovalent organic group other than R^{A}. However, when functional group R^{A} is introduced by a hydrosilylation reaction with its precursor, a hydrosilane compound having a silicon atom-bonded hydrogen atom and a (meth)acrylic functional group, at least some R′ may be and preferably should be an alkenyl group with 2 to 12 carbon atoms. In particular, it is particularly preferable to introduce functional group RA into the molecule by linking the organopolysiloxane resin with a chain organopolysiloxane, synthesizing component (A) itself or its precursor, and then reacting the alkenyl group, or R′, in the molecule with a hydrosilane compound having a (meth)acrylic functional group.

The method for linking the organopolysiloxane resin providing the X block and the chain organopolysiloxane providing the Y block is not particularly limited as long as it is a reaction capable of chemically linking the two blocks (hereinafter sometimes referred to as “block polymerization”), but industrially, a reaction providing a siloxane bond or a silalkylene bond is preferable, and examples include a condensation reaction and a hydrosilylation reaction. In the case of the former, the blocks are linked by a siloxane bond, and in the case of the latter, the blocks are linked by a silalkylene bond. More specifically, the linkage reactions between blocks include dehydration condensation reactions of silanols, decarboxylation condensation reactions of silanols and acetoxysilanes, dehydrogenation condensation reactions of silanols and hydrogensilanes, hydrolysis condensation of alkoxysilanes, and hydrosilylation between alkenyl groups and silicon atom-bound hydrogen atoms.

When a condensation reaction is used for block polymerization, an acid or base should be used as a catalyst. A weak acid or base is suitable to maintain the structure of each siloxane block. Examples include ammonia, acetic acid, and benzoic acid.

When a hydrosilylation reaction is used for block polymerization, the catalyst should be a low-valence transition metal complex or a Lewis acid such as borane, more suitably a hydrosilylation reaction catalyst that is a known platinum-based metal complex.

Component (A), the resin-linear structure-containing organopolysiloxane block copolymer, itself, or its precursor polymer, is obtained by combining an MQ-type organopolysiloxane resin giving block X and a chain organopolysiloxane giving block Y by block polymerization as described above, so it is relatively easy to control the molecular weight by selecting raw materials. In particular, from the standpoint of the hot-melt properties of the composition, when the molecular weight of component (A) is measured by gel permeation chromatography (GPC), etc., the molecular weight distribution curve should have at least one maximum.

Component (A) has hot-melt properties and is non-fluid or has a complex viscosity greater than 10,000 Pa·s at 25° C. However, the complex viscosity (=melt viscosity) at 80° C. is preferably in a range less than 10,000 Pa s, more preferably in the range of 100 to 10,000 mPa·s, and even more preferably in the range of 200 to 9,000 mPa·s. Such component (A) can be used to design a curable hot-melt silicone composition simply by combining it with a radical polymerization initiator (B).

### [Component (B)]

Component (B) is a radical polymerization initiator, which may be a photo-radical polymerization initiator (B1), a thermal radical polymerization initiator (B2), or a combination thereof. The type of component (B), curing method, and curing temperature used may be selected according to the sealing process using this composition and the heat resistance of the object to be sealed. Since component (A) in the present invention has, in addition to hot-melt properties, silicon atom-bound functional groups including radical polymerizable acrylic or methacrylic groups in the molecule, and optionally alkenyl groups, good curability can be achieved by high energy beam irradiation and/or heating in the presence of component (B).

The amount of component (B) used is 0.1 to 10 parts by mass per 100 parts by mass of component (A), and an amount of 0.2 to 5 parts by mass is especially preferred. The amount of component (B) to be used can be appropriately designed within the above range depending on the sealing process and curing time used in the application of the composition, the silicon atom-bonded functional group (R^{A}) content derived from component (A), and the dose of high energy radiation and/or the heating conditions.

Component (B1) is a photo-radical polymerization initiator, which accelerates the photo-curing reaction of the acrylic group or methacrylic group of the silicon-bonded functional group (R^{A}) in component (A) by high energy beam irradiation.

The photo-radical polymerization initiators are known to be broadly classified into photo-fragmentation and hydrogen abstraction types. However, the photo-radical polymerization initiator used in the composition of the present invention can be selected arbitrarily from those known in the technical field, and is not limited to any particular one. Some photo-radical polymerization initiators can promote a curing reaction not only by irradiation with high-energy beams such as ultraviolet light but also by light irradiation in the visible light region.

Specific examples of photo-radical polymerization initiators include α-ketol compounds such as 4-(2-hydroxyethoxy)phenyl (2-hydroxy-2-propyl) ketone, α-hydroxy-α, α′-dimethylacetophenone, 2-methyl-2-hydroxypropiophenone, 1-hydroxycyclohexyl phenyl ketone, and the like; acetophenone compounds such as methoxyacetophenone, 2,2-dimethoxy-2-phenylacetophenone, 2,2-diethoxyacetophenone, 2-methyl-1-[4-(methylthio)-phenyl]-2-morpholinopropane-1, and the like; benzoin ether compounds such as benzoin ethyl ether, benzoin isopropyl ether, anisoin methyl ether, and the like; ketal compounds such as benzyl dimethyl ketal and the like; aromatic sulfonyl chloride compounds such as 2-naphthalenesulfonyl chloride and the like; photo-active oxime compounds such as 1-phenone-1,1-propanedione-2-(o-ethoxycarbonyl)oxime and the like; benzophenone compounds such as benzophenone, benzoylbenzoic acid, 3,3′-dimethyl-4-methoxybenzophenone, and the like; thioxanthone compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, 2,4-diisopropylthioxanthone, and the like; camphorquinone; halogenated ketones and the like.

Similarly, suitable photo-radical polymerization initiators that can serve as component (B1) in the present invention include bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propylphenylphosphine oxide, bis(2,4,6-trimethylbenzoyl)-phenylphosphine oxide, bis(2,6-dimethoxybenzoyl)-2,4,4-trimethylpentylphosphine oxide, bis(2,6-dichlorobenzoyl)-4-propylphenylphosphine oxide, bis(2,6-dichlorobenzoyl)-2,5-dimethylphenylphosphine oxide, bis-(2,6-dimethoxybenzoyl)-2,5-dimethylphenylphosphine oxide, bis-(2,4,6-trimethylbenzoyl)-phenylphosphine oxide and other bisacylphosphine oxides; 2,6-dimethoxybenzoyl diphenylphosphine oxide, 2,6-dichlorobenzoyldiphenylphosphine oxide, 2,4,6-trimethylbenzoylphenylphosphinic acid methyl ester, 2-methylbenzoyldiphenylphosphine oxide, pivaloylphenylphosphinic acid isopropyl ester, 2,4,6-trimethylbenzoyldiphenylphosphine oxide, and other monoacylphosphine oxides; anthraquinone, chloroanthraquinone, 2-methylanthraquinone, 2-ethylanthraquinone, 2-tert-butylanthraquinone, 1-chloroanthraquinone, 2-amylanthraquinone, 2-aminoanthraquinone, and other anthraquinones; ethyl 4-dimethylaminobenzoate, 2-(dimethylamino)ethyl benzoate, p-dimethylbenzoic acid ethyl ester, and other benzoates; bis(η5-2,4-cyclopentadien-1-yl)-bis(2,6-difluoro-3-(1H-pyrrol-1-yl)phenyl)titanium, bis(cyclopentadienyl)-bis[2,6-difluoro-3-(2-(1-pyr-1-yl)ethyl)phenyl]titanium, and other titanocenes; and phenyl disulfide 2-nitrofluorene, butyroin, anisoin ethyl ether, azobisisobutyronitrile, and tetramethylthiuram disulfide.

Examples of commercially available acetophenone-based photopolymerization initiators suitable for use as Component (B1) in the present invention include Omnirad 907, 369, 369E and 379 manufactured by IGM Resins. Examples of commercially available acylphosphine oxide-based photopolymerization initiators include Omnirad TPO, TPO-L, and 819 manufactured by IGM Resins. Examples of commercially available products include oxime ester-based photopolymerization initiators such as Irgacure OXE01 and OXE02 manufactured by BASF Japan Ltd., N-1919, Adeka Arkls NCI-831 and NCI-831 E manufactured by ADEKA CORPORATION, and TR-PBG-304 manufactured by Changzhou Tronly New Electronic Materials Co., Ltd.

Component (B2) is a thermal radical polymerization initiator that generates radical species upon heating and accelerates the curing reaction of the acrylic or methacrylic group of the silicon atom-bound functional group (R^{A}) in component (A). Such thermal radical polymerization initiators include azo compounds and organic peroxides.

Examples of azo compounds include 2,2′-azobisisobutyronitrile, 2,2′-azobis(2-methylbutyronitrile), 2,2′-azobis(2,4-dimethylvaleronitrile), 1,1′-azobis-1-cyclohexanecarbonitrile, dimethyl-2,2′-azobisisobutyrate, dimethyl-2,2′-azobis(2-methylpropionate), dimethyl-1,1′-azobis(1-cyclohexanecarboxylate), 4,4′-azobis(4-cyanovaleric acid), 2,2′-azobis(2-amidinopropane) dihydrochloride, 2-tert-butylazo-2-cyanopropane, 2,2′-azobis(2-methylpropionamide) dihydrate, and 2,2′-azobis(2,4,4-trimethylpentane).

Examples of organic peroxides include alkyl peroxides, diacyl peroxides, ester peroxides, and carbonate peroxides. Examples of alkyl peroxides include dicumyl peroxide, di-tert-butyl peroxide, di-tert-butylcumyl peroxide, 2,5-dimethyl-2,5-di(tert-butylperoxy)hexane, 2,5-dimethyl-2,5-di(tert-butylperoxy)hexyne-3, tert-butylcumyl, 1,3-bis(tert-butylperoxyisopropyl)benzene, and 3,6,9-triethyl-3,6,9-trimethyl-1,4,7-triperoxonan. Examples of diacyl peroxides include benzoyl peroxide, lauroyl peroxide, and decanoyl peroxide. Examples of ester peroxides include 1,1,3,3-tetramethylbutylperoxyneodecanoate, α-cumylperoxyneodecanoate, tert-butylperoxyneodecanoate, tert-butylperoxyneoheptanoate, tert-butylperoxypivalate, tert-hexylperoxypivalate, 1,1,3,3-tetramethylbutylperoxy-2-ethylhexanoate, tert-amylperoxyl-2-ethylhexanoate, tert-butylperoxy-2-ethylhexanoate, tert-butylperoxyisobutyrate, di-tert-butylperoxyhexahydroterephthalate, tert-amylperoxy-3,5,5-trimethylhexanoate, tert-butylperoxy-3,5,5-trimethylhexanoate, tert-butylperoxyacetate, tert-butylperoxybenzoate, and di-butylperoxytrimethyladipate. Examples of carbonate peroxides include di-3-methoxybutyl peroxydicarbonate, di(2-ethylhexyl)peroxydicarbonate, diisopropyl peroxycarbonate, tert-butyl peroxyisopropylcarbonate, di(4-tert-butylcyclohexyl)peroxydicarbonate, dicetyl peroxydicarbonate, and dimyristyl peroxydicarbonate.

### [Component (B′): Photosensitizer]

The composition may optionally use a photosensitizer (B′) in combination with a photo-radical polymerization initiator (B1). Use of a sensitizer can increase the photon efficiency of the polymerization reaction, and is particularly effective when the coating thickness of the composition is relatively thick or when a relatively long-wavelength LED light source is used, because use of longer wavelength light for the polymerization reaction compared to only using a photoinitiator is feasible. Examples of known sensitizers include anthracene-based compounds, phenothiazine-based compounds, perylene-based compounds, cyanine-based compounds, melocyanine-based compounds, coumarin-based compounds, benzylidene ketone-based compounds, and (thio)xanthene- or (thio)xanthone-based compounds such as isopropylthioxanthone, 2,4-diethylthioxanthone, squarylium-based compounds, (thia)pyrylium-based compounds, porphyrin-based compounds, and the like. Moreover, an arbitrary photosensitizer not limited thereto can be used in the curable organopolysiloxane composition and pressure-sensitive adhesive composition of the present invention. Any amount can be used, but a range is commonly selected in which the mass ratio of component (B′) to component (B1) is 0 to 10, or 0.01 to 5 when used.

### [Selection of Component (B) and the Curing Method]

Since the composition contains component (A) and component (B) described above, it forms a cured product by radical polymerization reaction. When at least some of component (B) is a photo-radical polymerization initiator (B1), the composition can be cured by irradiating it with a high-energy beam such as ultraviolet light. Similarly, when at least some of component (B) is a thermal radical polymerization initiator (82), the composition can be cured by heating. Furthermore, a combination of both can be used for curing, with heating and high-energy beam irradiation selected or combined, depending on the desired curing method and sealing process.

In particular, the composition of the present invention is suitable for a process in which component (A) has hot-melt properties and (meth) acrylic group-containing groups, which are melted by heating to fill irregularities in the base material or member to be sealed and then cured in a low-stress state. A light curing process involving irradiation with high-energy rays can be suitably used because it enables rapid curing reactions even at low temperatures, including room temperature, even for base materials and components with poor heat resistance, and the cured product has excellent transparency and UV yellowing resistance. In such cases, preferably, at least some of component (B) is a photo-radical polymerization initiator (B1), and a photosensitizing agent (B′) is optionally included. However, if the base material and members in the sealing process have sufficient heat resistance, rapid curing at high temperatures is possible when at least some of component (B) is a thermal radical polymerization initiator (B2).

### [Component (C)]

The composition according to the present invention may further contain (C) an organopolysiloxane resin containing in the molecule an M unit and a Q unit, represented by R^{B}₃SiO_{1/2} and R^{A}ₐR^{B}₍₃₋ₐ₎SiO_{1/2}, the ratio of the amount of substance of M unit to Q unit being in a range of 0.5 to 2.0. In the formula, a represents an integer of 1 to 3, R^{A} is a silicon-bonded functional group containing an acrylic group or a methacrylic group, and R^{B} is a monovalent organic group other than R^{A}. Examples include the same groups described above. At least one of the M units constituting component (C) is a triorganosiloxy unit containing a functional group R^{A} represented by R^{A}ₐR^{B}₍₃₋ₐ₎SiO_{1/2}.

Component (C) is an MQ-type organopolysiloxane resin having an acrylic group or a methacrylic group in the molecule, and has at least one silicon-bonded functional group containing an acrylic group or a methacrylic group represented by R^{A} in the molecule, and therefore participates in the same curing reaction as component (A). Component (C) is an optional component that adjusts the adhesion to the base material, the crosslink density of the cured product, and the melt viscosity, and depending on the amount of component used, can adjust the hardness of the cured product of the composition and its adhesion to the base material.

Component (C) component may contain a small amount of siloxane units (T units) represented by RSiO_{3/2} (where R is a monovalent organic group that may contain R^{A} above) or siloxane units (D units) represented by R₂SiO_{2/2} (where R is the same monovalent organic group as above). However, preferably the material consists substantially only of M units and Q units represented by R^{B}₃SiO_{1/2} and R^{A}ₐR^{B}₍₃₋ₐ₎SiO_{1/2} described above, and the sum of the amount of substance of T unit and D units per mole of Q units in component (C) is preferably less than 0.1 mole.

The ratio (molar ratio) of the amount of substance of M units to Q units in component (C) is in the range of 0.5 to 2.0, preferably in the range of 0.5 to 1.5, more preferably in the range of 0.55 to 1.20, and even more preferably in the range of 0.60 to 1.10.

Any amount of component (C) can be used as it is restricted, but the amount is preferably in the range of 0.1 to 50 parts by mass per 100 parts by mass of component (A), and an amount in the range of 0.1 to 25 parts by mass is especially preferred.

### [Component (C′)]

The composition of the present invention may optionally contain chain organopolysiloxanes with silicon atom-bound functional groups (R^{A}), including acrylic or methacrylic groups, which do not fall under components (A) or (C). Specifically, the present composition may contain one or more chain organopolysiloxanes selected from components (C′1) and (C′2) described below.

Component (C′1) is a linear organopolysiloxane having at least one functional group (R^{A}) in the molecule, as shown in structural formula (C′-1) described below.

### Structural Formula (C′-1):

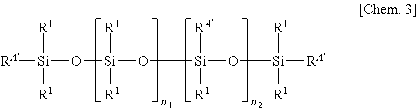

In the formula, each R¹ independently represents a C1-C6 alkyl group, a C2-C20 alkenyl group, or a C6-C12 aryl group, R^{A′} is a group selected from C1-C6 alkyl groups, C2-C20 alkenyl groups, C6-C12 aryl groups, and the silicon atom-bound functional groups (R^{A}) including acrylic groups or methacrylic groups described above, n1 is a positive number, and n2 is zero or a positive number. However, when n2 is 0, at least one R^{A′} is a silicon-bonded functional group containing an acrylic group or a methacrylic group (R^{A}). n1+n2 is 0 or a positive number and is not limited, but is preferably in the range of 10 to 5000, more preferably 10 to 2000, and even more preferably 10 to 1000. Note that the value of n1+n2 may be and is preferably a number such that the viscosity of component (C′1) at 25° C. satisfies the viscosity range of 1 to 100,000 mPa·s, more preferably 10 to 50,000 mPa·s, and even more preferably 500 to 50,000 mPa·s.

Component (C′2) is a branched-chain organopolysiloxane having at least functional group (R^{A}) in the molecule and containing branched siloxane units, as shown in average unit formula (C′-2) described below. Unlike component (A) or (C), component (C′2) does not contain an MQ-type organopolysiloxane resin structure, and T unit or Q units are included in the molecule only as branched units of a chain organopolysiloxane.

### Average Unit Formula (C′-2):

(R^{A′}R₂SiO_{1/2})x(R¹₂SiO_{2/2})_{y1}(R^{A′}R¹SiO_{2/2})_{y2}(R¹SiO_{3/2})_{z1}(R^{A′}SiO_{3/2})_{z2} (1-2)

In the above formula, R¹, R^{A′} represents the same groups as described above, x, y1, y2, z1 and z2 represent the ratio of the amount of substance when the sum of each siloxane unit is 1. Specifically, if x+y1+y2+z1+z2=1, 0<x≤0.2, 0.3≤y1+y2<1, 0<z1+z2≤0.2, and y2+z2=0, at least one of the R^{A′} is a silicon atom-bound functional group (R^{A}) containing the acrylic or methacrylic group described above. Note that one or both of y2 and z2 may be 0.

More specifically, component (C′2) is a branched organopolysiloxane represented by the following siloxane unit formula.

(R^{A′}R¹₂SiO_{1/2})ₐ(R¹₂SiO_{2/2})_{b1}(R^{A′}R¹SiO_{2/2})_{b2}(R¹SiO_{3/2})_{c1}(R^{A′}SiO_{3/2})_{c2}

(In the formula, R¹ and R^{A′} are the same as the groups described above.)
When represented by this, 0<a≤10, 15≤b1+b2<2000, 0<c1+c2≤10, and b2+c2=0, at least one of R^{A′} is a silicon atom-bound functional group (R^{A}) containing the acrylic or methacrylic group mentioned above.

As an example, component (C′2) may be a branched-chain organopolysiloxane having methacryloyl group-containing organic groups only on the terminal M units represented by the siloxane unit formula below.

(R^{A′}R¹₂SiO_{1/2})ₐ(R¹₂SiO_{2/2})_{b1}(R¹SiO_{3/2})_{c1}

In the formula, R¹ and R^{A′} are the same groups as above, 0<a≤10, 15≤b1<2000, 0<c1≤10, and at least one of R^{A′} is a silicon atom-bound functional group (R^{A}) containing acrylic or methacrylic groups as above.

The viscosity of component (C′2) at 25° C. is preferably 10 to 50,000 mPa·s, and more preferably 100 to 2,000 mPa·s.

Like component (C), the chain organopolysiloxane in component (C′) has a silicon atom-bound functional group containing at least one acrylic or methacrylic group represented by R_{A} in the molecule, and thus is involved in a curing reaction similar to component (A). Component (C′) is an optional component that adjusts the adhesion to the base material, the crosslink density of the cured product, and the melt viscosity. Depending on the amount of the component used, it is possible to adjust the hardness of the cured product of this composition and its adhesion to the base material, and may be particularly useful in adjusting the crosslink density, etc.

The amount of chain organopolysiloxane used as component (C′) is not particularly restricted, but the amount is preferably in the range of 0.1 to 50 parts by mass per 100 parts by mass of component (A), and more preferably in the range of 0.1 to 25 parts by mass.

### [Component (D)]

The composition of the present invention may further comprise (D) an organopolysiloxane resin containing an M unit and a Q unit, represented by R^{B}₃SiO_{1/2} in the molecule, at the ratio of M unit to Q unit being in the range of 0.5 to 2.0. In the formula, R^{B} is a monovalent organic group excluding R^{A}, and the same groups as above are exemplified. Unlike component (C), component (D) does not contain functional group R^{A} and a siloxane unit containing R^{A} in the molecule.

Component (D) is an MQ type organopolysiloxane resin having no acrylic group or methacrylic group in the molecule, and is not involved in the same curing reaction as component (A), but is an optional component for adjusting the adhesion to the base material, the crosslinking density of the cured product, and the melt viscosity. Depending on the amount of the component used, it is possible to adjust the hardness of the cured product of this composition and its adhesion to the base material.

Component (D) may contain a small amount of a siloxane unit represented by R^{B}SiO_{3/2} (T unit) or a siloxane unit represented by R^{B}₂SiO_{2/2} (D unit), but preferably consists essentially of only M units represented by R^{B}₃SiO_{1/2} and Q units, and the sum of the amount of T units and D units per mole of Q units in component (D) is preferably less than 0.1 mole.

The ratio (molar ratio) of the amount of substance of M units to u units in component (D) is in the range of 0.5 to 2.0, preferably in the range of 0.5 to 1.5, more preferably in the range of 0.55 to 1.20, even more preferably in the range of 0.60 to 1.10.

Any amount of component (D) can be used and is not restricted, but the amount is preferably in the range of 0.1 to 200 parts by mass per 100 parts by mass of (A) component, more preferably in the range of 5 to 150 parts by mass, and even more preferably in the range of 10 to 100 parts by mass.

### [Component (E)]

The composition of the present invention may further comprise (E) polydimethylsiloxane, which may optionally have alkenyl groups. Since component (E) has fluidity itself, and the melting characteristics of the composition, adhesion of the cured product to the base material, hardness, crosslink density, etc., can sometimes be adjusted by using this together with component (A), etc. described above.

More specifically, component (E) is a polydimethylsiloxane which is liquid or is plastic at 25° C. and which optionally has at least two alkenyl groups having 2 to 20 carbon atoms in the molecule. Component (A) is explicitly excluded from the range for component (E), and suitable examples of component (E) include cyclic, linear, branched, resinous and raw rubber polydimethylsiloxanes in which a methyl group attached to a silicon atom may be partially substituted by an alkenyl group having 2 to 20 carbon atoms.

The siloxane degree of polymerization and viscosity range of the polydimethylsiloxane in component (E) is not particularly limited, but it may be a liquid polydimethylsiloxane with a viscosity in the range of 1.5 to 1,000,000 mPa·s at 25° C. and a viscosity of 100,000 mPa·s or more at 25° C., or a raw rubber-like polydimethylsiloxane with a plasticity in the range of 50 to 200 as measured in accordance with the method specified in JIS K6249 (reading the thickness to 1/100mm when a load of 1 kgf is applied to a 4.2 g spherical sample at 25° C. for 3 minutes, and multiplying this value by 100). The amount of vinyl (CH2═CH) moiety in the alkenyl group in component (E) (hereinafter, referred to as the “vinyl content”) can be any amount, but may be in the range of 0.000 to 1.500 mass % or 0.050 to 1.000 mass %. Note that a cyclic polydimethylsiloxane with a degree of siloxane polymerization of 3 to 20, which may optionally have an alkenyl group, is included in the range of component (E). When the (E) component is a chain molecule, the molecular chain ends may have a structure capped by a non-reactive trialkylsilyl group such as a trimethylsilyl group, or by a reactive functional group such as a vinyl dimethylsilyl group or another alkenyldimethylsilyl group, an alkoxydimethylsilyl group, or a hydroxydimethylsilyl group.

### [Organic Solvent (F)]

The compositions of the present invention may optionally contain (F) an organic solvent. The organic solvent may be used as a diluent to disperse or dissolve each component in order to improve the coatability and wettability of the composition on the substrate, or may be unavoidably included as solvents associated with other raw material components.

While not particularly limited, as long as the technical effects of the present invention are not impaired, the type of organic solvent used herein may be a compound which is soluble with all of the constituent components in the composition or a portion of the constituent components, and a type having a boiling point of 80° C. or higher and of 200° C. or lower is preferably used. The type of solvent can be a non-halogenated or halogenated solvent, aromatic hydrocarbon solvent, aliphatic hydrocarbon solvent, ester solvent, alcohol solvent, ether solvent, chlorinated aliphatic hydrocarbon solvent, volatile oil solvent, or the like, and combinations of two or more types can be used depending on the coatability, wettability, and the like.

More specifically, examples include non-halogen solvents such as i-propyl alcohols, t-butyl alcohol, cyclohexanol, cyclohexanone, methyl ethyl ketone, methyl isobutyl ketone, toluene, xylene, benzene, heptane, hexane, octane, isoparaffin, mesitylene, 1,4-dioxane, dibutyl ether, anisole, 4-methyl anisole, ethyl benzene, ethoxy benzene, ethylene glycol, diisopropyl ether, 1,4-dioxane, ethylene glycol dimethyl ether, ethylene glycol diethyl ether, 2-methoxy ethanol (ethylene glycol monomethyl ether), diethylene glycol dimethyl ether, diethylene glycol monomethyl ether, dipropylene glycol methyl ether acetate, ethyl acetate, butyl acetate, propyl propionates (=propyl propionate), 1-methoxy-2-propyl acetate, 1-ethoxy-2-propyl acetate, octamethyl cyclotetrasiloxane, hexamethyl disiloxane, and the like; and halogen solvents such as trichloroethylene, perchloroethylene, methylene chloride, trifluoromethyl benzene, 1,2-bis (trifluoromethyl)benzene, 1,3-bis (trifluoromethyl)benzene, 1,4-bis (trifluoromethyl)benzene, trifluoromethyl chlorobenzenes, trifluoromethyl fluorobenzene, hydrofluoroether, and the like.

Because the composition is a low-fluidity or non-fluidity hot-melt silicone composition at 25° C., the amount of organic solvent (F) should be small enough that a large amount of organic solvent does not impair the hot melt properties. For example, the amount of component (F) is preferably from 0 to less than 5 mass % per 100 mass of the entire composition. In particular, when forming the composition into a sheet or film as described below, the component (F) used in the forming process is preferably removed by heating, etc.

### [Adhesion-Imparting Agent (G)]

The present composition may further comprise a known adhesion-imparting agent as component (G). Component (G) improves the adhesive strength of the cured product obtained by curing the present composition to a base material, and one or more types of known adhesion-imparting agents can be selected and used. In particular, the use of a compound with two or more alkoxysilyl groups in the molecule as at least some of the (G) component may greatly improve adhesive strength after a certain amount of time.

The amount of component (G) used is 0.01 to 5 parts by mass when the total composition of the invention is 100 parts by mass, and the amount of 0.02 to 2 parts by mass is particularly preferred. If the amount of component (G) used is less than the lower limit described above, the adhesive strength to the base material may not be sufficiently improved, and if the amount exceeds the upper limit described above, the compatibility with other components may deteriorate or the appearance of the cured material may be affected over time.

Preferably, component (G) contains an organic compound having two or three alkoxysilyl groups at the end of the molecular chain. Furthermore, the organic compound herein include organic silicon compounds in addition to alkane compounds and the like.

Specific examples of an organic compound having two or three alkoxysilyl groups at the end of the molecular chain include 1,2-bis(trimethoxysilyl) ethane, 1,2-bis(triethoxysilyl) ethane, 1,2-bis(methyldimethoxysilyl) ethane, 1,2-bis(methyldiethoxysilyl) ethane, 1,3-bis(trimethoxysilyl) propane, 1,4-bis(trimethoxysilyl) butane, 1,4-bis(triethoxysilyl) butane, 1-methyldimethoxysilyl-4-trimethoxysilylbutane, 1-methyldiethoxysilyl-4-triethoxysilylbutane, 1,4-bis(methyldimethoxysilyl) butane, 1,4-bis(methyldiethoxysilyl) butane, 1,5-bis(trimethoxysilyl) pentane, 1,5-bis(triethoxysilyl) pentane, 1,4-bis(trimethoxysilyl) pentane, 1,4-bis(triethoxysilyl) pentane, 1-methyldimethoxysilyl-5-trimethoxysilylpentane, 1-methyldiethoxysilyl-5-triethoxysilylpentane, 1,5-bis(methyldimethoxysilyl) pentane, 1,5-bis(methyldiethoxysilyl) pentane, 1,6-bis(trimethoxysilyl) hexane, 1,6-bis(triethoxysilyl) hexane, 1,4-bis(trimethoxysilyl) hexane, 1,5-bis(trimethoxysilyl) hexane, 2,5-bis(trimethoxysilyl) hexane, 1-methyldimethoxysilyl-6-trimethoxysilylhexane, 1-phenyldiethoxysilyl-6-triethoxysilylhexane, 1,6-bis(methyldimethoxysilyl) hexane, 1,7-bis(trimethoxysilyl) heptane, 2,5-bis(trimethoxysilyl) heptane, 2,6-bis(trimethoxysilyl) heptane, 1,8-bis(trimethoxysilyl) octane, 1,8-bis(methyldimethoxysilyl) octane, 2,5-bis(trimethoxysilyl) octane, 2,7-bis(trimethoxysilyl) octane, 1,9-bis(trimethoxysilyl) nonane, 2,7-bis(trimethoxysilyl) nonane, 1,10-bis(trimethoxysilyl) decane, 3,8-bis(trimethoxysilyl) decane, and other alkane compounds having two alkoxydisilyl groups, 1,3-bis{2-(trimethoxysilyl) ethyl}-1,1,3,3-tetramethyldisiloxane, 1,3-bis{2-(methyldimethoxysilyl) ethyl}-1,1,3,3-tetramethyldisiloxane, 1,3-bis{2-(triethoxysilyl) ethyl}-1,1,3,3-tetramethyldisiloxane, 1,3-bis{2-(methyldiethoxysilyl) ethyl}-1,1,3,3-tetramethyldisiloxane, 1,3-bis{6-(trimethoxysilyl) hexyl}-1,1,3,3-tetramethyldisiloxane, 1,3-bis{6-(triethoxysilyl) hexyl}-1,1,3,3-tetramethyldisiloxane, and other disiloxane compounds having two alkoxysilyl groups.

Furthermore, examples of organic compounds having three alkoxysilyl groups include 1,3,5-tris{2-(trimethoxysilyl) ethyl}-1,1,3,5,5-pentamethyl trisiloxane, 1,3,5-tris{2-(methyldimethoxysilyl) ethyl}-1,1,3,5,5-tetramethyldisiloxane, 1,3,5-tris{2-(triethoxysilyl) ethyl}-1,1,3,5,5-tetramethyldisiloxane, 1,3,5-tris{2-(methyldiethoxysilyl) ethyl}-1,1,3,5,5-tetramethyl disiloxane, 1,3,5-tris{6-(trimethoxysilyl) hexyl}-1,1,3,5,5-tetramethyl disiloxane, and other trisiloxane compounds having three alkoxysilyl groups. An example of the structure is:

(MeO)₃SiCH₂CH₂(Me)₂Si—O—SiMe(CH₂CH₂Si(OMe)₃)—O—Si(Me)₂CH₂CH₂Si(OMe)₃

(where Me represents a methyl group).

In addition to silane compounds such as 3-glycidoxypropyltrimethoxysilane, as well as organosiloxane oligomers and alkyl silicates, examples that can be used as component (G) in the present invention include reaction mixtures of amino group-containing organoalkoxysilanes and epoxy group-containing organoalkoxysilanes disclosed in JP 52-8854 A and JP 10-195085 A, especially carbasilatrane derivatives having silicon atom-bound alkoxy groups or silicon atom-bound alkenyl groups in the molecule and silatrane derivatives having organic groups containing alkoxysilyl groups can be preferably used. These are also disclosed in Patent Documents 1-4 listed above, and an appropriate adhesion-imparting agent can be selected from these.

### [Thiol Compound (H)]

The compositions according to the present invention may further contain (H) a multifunctional thiol compound having at least two thiol groups in the molecule. Multifunctional thiol compounds act as chain transfer agents to promote radical polymerization reactions, and in particular when some of component (B) in the present invention is a photo-radical polymerization initiator and the composition is cured by UV or some other high energy beam irradiation,

it can improve the curing speed and the depth-curing properties of the cured materials even when the irradiation dose of high-energy beams is low, and also serve as a cross-linking point in the composition.

Examples of the multifunctional thiol compound include pentaerythritol tetrakis(3-mercaptobutyrate), 1,4-bis(3-mercaptobutyryloxy)butane, 1,3,5-tris(2-(3-sulfanylbutanoyloxy)ethyl)-1,3,5 triazinane-2,4,6-trione, trimethylolpropane tris(3-mercaptobutyrate), and the like.

The use of component (H) is optional, the amount thereof is 0 to 20 parts by mass relative to 100 parts by mass of component (A), preferably 0 to 10 parts by mass, and more preferably 0 to 5 parts by mass.

In addition, as long as they do not impair the purpose of the invention, the composition may contain, as another optional component, one or more of the following: heat-resistant agents such as iron oxide (red iron oxide), cerium oxide, cerium dimethylsilanolate, cerium salts of fatty acids, cerium hydroxide, and zirconium compounds; antioxidants such as phenolic, quinone, amine, phosphorus, phosphite, sulfur, or thioether-based antioxidants; light stabilizers such as triazoles or benzophenones; flame retardants such as phosphate, halogen, phosphorus, or antimony-based flame retardants; and one or more antistatic agents consisting of cationic surfactants, anionic surfactants, or nonionic surfactants. In addition to these components, pigments, dyes, inorganic particles (reinforcing fillers, dielectric fillers, conductive fillers, thermally conductive fillers), etc. can be optionally blended into the composition of the present invention, depending on its application.

The curable hot-melt silicone composition of the present invention may be used in the form of granules, pellets, sheets, films, or the like.

The present composition may be used molded in a sheet or film form. For example, a sheet or film made of the curable silicone composition of the present invention with an average thickness of 10 to 1000 μm has hot-melt properties and, depending on the type of component (B), is curable by a radical polymerization reaction triggered by high energy beam irradiation or heating, and thus has excellent handling workability and melting properties, and is particularly advantageous for use in overmolding.

### [Laminate Body Containing Curable Hot-Melt Silicone Composition and Use Thereof as Film Adhesive/Sealing Agent]

The present curable hot-melt silicone composition can be used in a sheet or film form, and can be particularly used as a laminate body having a structure in which a sheet-like material containing the curable hot-melt silicone composition described above is interposed between two film-like substrates provided with a release layer. The film-like base material provided with the release layer (generally referred to as release film) can be released from the sheet-like material containing the curable hot-melt silicone composition when the sheet-like material is used as an adhesive, sealing agent, or the like. The laminate body is also referred to as a releasable laminate body below.

A sheet or film of the curable hot-melt silicone composition described above can be obtained by performing the following:
Step (I): Application of the curable hot-melt silicone composition to a base material, and
Step (II): Heating and drying the composition applied in Step (I) to obtain a composition formed into a sheet or film. Here, when applying the curable hot-melt silicone composition in Step (I), it may be applied to the base material in a fluid state by heating and melting the composition itself, or may be applied to the base material in the form of a dispersion solution using an organic solvent. The organic solvent is then removed in Step (II). If a release layer is present on the base material, the sheet or film of curable hot-melt silicone composition can be obtained as part of the peelable laminate, which will be explained as follows.

Although there are no particular limitations on the method of manufacturing the peelable laminate, a method including the following steps can be mentioned as an example:
Step 1: Mixing the components of the curable hot-melt silicone composition,
Step 2: Kneading the mixture obtained in Step 1 while heating and melting,
Step 3: Laminating the mixture heated and melted in Step 2 between two release films with at least one release surface, so that the mixture is in contact with the release surfaces to form a laminate, and
Step 4: Pressing the laminate obtained in Step 3 between rolls to roll press the mixture interposed between the two release films and form a curable hot-melt silicone composition sheet or film with a specific film thickness. Furthermore, rollers with a cooling or temperature adjusting function may be optionally used in Step 4. Furthermore, a step of cutting a resulting laminate body containing the curable hot-melt silicone composition sheet or film may be added after Step 4. Instead of Step 2, the mixture obtained in Step 1 may be applied to the release film in the form of dispersion in an organic solvent, and the organic solvent may be removed by heating or other means before Step 3.

Note that the thickness of the release film is not particularly limited, and therefore, in addition to those generally referred to as a film, those referred to as a sheet are also included. However, in the present specification, it is referred to as a release film regardless of the thickness thereof.

The temperature of the mixing process in Step 1 above is not particularly limited, but heating may be performed as necessary to ensure that each component is sufficiently mixed. For example, the heating temperature can be 50° C. or higher.

By removing the release film from the peelable laminate, a sheet or film comprising the curable hot-melt silicone composition is obtained. Therefore, the present invention also provides such a sheet or film. The sheet or film of the present invention is preferably 10 to 1000 μm thick, and the sheet or film is preferably flat. Flat means that the thickness of the resulting sheet or film is within the range of ±100 μm or less, preferably within the range of ±50 μm or less, more preferably within the range of ±30 μm or less.

The type of base material for the release film that constitutes the peelable laminate is not limited, but polyester film, polyolefin film, polycarbonate film, or acrylic film, for example, can be used as appropriate. The sheet-like substrate is preferably non-porous. A release film is a film having a release layer formed by treating one or both sides of a film made of such a material to give it release properties, and such treatments are known in the art.

The release layer is a layer with release properties added to the surface of the release film. The release layer is a structure that allows the sheet or film made of curable silicone composition to be easily removed from the film base material, and is sometimes called a release liner, separator, mold release layer, or release coating layer. Suitably, the release layer can be formed as a release layer with release coating capability such as with a silicone release agent, fluorine release agent, alkyd release agent, or fluorosilicone release agent. Alternatively, the surface of the film base material may be physically formed with minute irregularities to reduce adhesion to the curable silicone composition, or the base material may be made of a material that adheres only with difficulty to the curable hot-melt silicone composition of the invention or to a layer comprising a cured product thereof. In particular, the use of a release layer consisting of a fluorinated release agent or fluorosilicone release agent cured as a release layer is preferred in the laminate of the present invention.

The laminate described above can be used, for example, by peeling off one of the two release films comprising the laminate, applying the uncured sheet or film-like member consisting of the curable silicone composition that is not in contact with the release film to the adherend, and then peeling off the uncured sheet or film-like member from the other film-like base material, that is, the release film.

The curable silicone composition can be handled at room temperature in granular, pellet or sheet form is a low-flow or no-flow solid at 25° C. Here, non-flowability means that the curable silicone composition does not deform and/or flow in the absence of external force, and suitably, the curable silicone composition does not deform and/or flow at 25° C. and in the absence of external force when molded into pellets or tablets. Such non-flowability can be assessed, for example, by placing the molded composition on a hot plate at 25° C. and applying no external force or a certain amount of weight to the composition, and making sure substantial deformation and/or flow of the composition does not occur. If the composition is non-flowable at 25° C., handling even in an uncured state is simple because shape retention of the composition is favorable at that temperature and the surface adhesion thereof is low.

The softening point of the composition is preferably 100° C. or less. Such a softening point means the temperature at which the deformation amount of the composition in the height direction is 1 mm or more when the composition is pressed for 10 seconds from above with a 100 gram load at a height of 22 mm on a hot plate and the deformation of the composition is measured after the load is removed.

### [Curable Hot-Melt Silicone Composition Sheet]

The curable hot-melt silicone composition sheet obtained by the manufacturing method of the present invention is a curable silicone composition containing each of the above-mentioned components and has hot-melt properties. The curable hot-melt silicone composition sheet of the present invention can be used as a pressure sensitive adhesive material, sealing agent, and/or adhesive, or the like, having heat-melting properties. In particular, the curable hot-melt silicone composition sheet has excellent moldability, gap filling properties, and pressure sensitive adhesive force, and can be used as a die attach film or film adhesive. It can also be suitably used as a curable hot-melt silicone composition sheet for overmolding, compression molding or press molding.

Specifically, after peeling the curable hot-melt silicone composition sheet obtained by the manufacturing method of the present invention from the release film, the sheet is placed at the desired site on a semiconductor or other device and melted by heating to form a film adhesive layer on and between the adherends, taking advantage of its gap-filling property against irregularities and gaps on the base material. Temporary fixing, placement, and bonding between adherends are performed, the curable hot-melt silicone composition layer is cured by irradiation or heating with high-energy beams, and the adherends are bonded by forming a cured product of the curable silicone sheet between the adherends. Note that the release film may be released after the curable hot-melt silicone composition sheet is heated to form a cured product, and a timing for releasing the release film from the curable silicone composition or cured product obtained therefrom may be selected based on an application and method of use of the curable silicone composition sheet.

The curable silicone composition sheet has hot-melt properties, and therefore, it is possible to soften or fluidize the sheet by heating the sheet prior to final curing, and for example, thereby forming an adhesive surface with an adherend by filling protrusions and recesses or gaps without a void even if there are irregularities on the adhesive surface of the adherend. Examples of heating means of the curable hot-melt silicone composition sheet that can be used include various thermostatic baths, hot plates, electromagnetic heating devices, heating rollers, and the like. In order to more efficiently adhere the adherend and curable silicone composition sheet together and heat the curable silicone composition, an electric heating press, a diaphragm type laminator, a roll laminator, or the like is preferably used, for example.

### [Method of Forming Cured Product]

As already mentioned, the curable hot-melt silicone composition of the present invention can be designed as a light-curable composition curable by irradiation with high energy beams, or can be designed as a heat-curable composition curable by heating, depending on the selection of component (B).

When at least some of component (B) is a photo-radical polymerization initiator (B1), the curable silicone composition of the present invention can form a cured product by irradiating the composition (or semi-cured product thereof) with high-energy beams such as UV light, which causes a radical polymerization reaction to proceed.

Examples of high energy beams that can be used include UV light, gamma rays, X-rays, alpha rays, and electron beams. In particular, examples include ultraviolet rays, X-rays, and electron beams irradiated from a commercially available electron beam irradiating device. Of these, ultraviolet rays are preferable from the perspective of efficiency of catalyst activation, and ultraviolet rays within a wavelength range of 280 to 380 nm are preferable from the perspective of industrial use. Furthermore, the irradiation dose varies depending on the type of high energy beam activated catalyst, but in the case of ultraviolet light, the integrated irradiation dose at a wavelength of 365 nm is preferably within a range of 100 mJ/cm² to 100 J/cm².

The curing reaction does not require heating, and therefore curing can be performed at a low temperature (15 to 100° C.), including room temperature (25° C.). Note that in an embodiment of the present invention, “low temperature” refers, for example, to 100° C. or lower, specifically, a temperature range of 15° C. to 100° C., and even temperatures of 80° C. or lower can be selected. When the reaction of the composition (including a semi-cured product) of the present invention proceeds in the temperature range of 15 to 100° C., the present composition may suitably be left at or near room temperature range (a temperature range that can be reached without heating or cooling, particularly including a temperature region of 20 to 25° C.), may be cooled to 15° C. to room temperature, or may be heated to room temperature or higher and 100° C. or lower. Note that the time required for the curing reaction can be designed as appropriate based on the irradiation dose of a high energy beam such as ultraviolet light or the like and the temperature. Furthermore, depending on process acceptability and necessity, heating above 100° C. may be temporarily performed, or heating and crimping may be performed at the same time to allow the curing reaction to proceed simultaneously with crimping.

When at least some of component (B) is a thermal radical polymerization initiator (B2), the curable silicone composition can be heated to 100° C. or higher to allow the radical polymerization reaction to proceed and form a cured product. The heating temperature can be selected according to the heat resistance of the base material and the sealing process, etc., and if the base material has high heat resistance, it can be heated to 150° C. or higher.

The cured product of the curable hot-melt silicone composition of the present invention is characterized by excellent resistance to yellowing under high temperature, high humidity, or UV exposure conditions. In other words, by using this composition, it is possible to obtain a cured product with a b* value of 2.0 or less, preferably 1.0 or less, after 500 hours in a high temperature exposure test at 150° C. or in an accelerated weathering test in accordance with ASTM G 154 Cycle 4 (hereinafter, QUV test) where the thickness of the cured product is 200 um. In particular, in known active energy beam-curable hot-melt silicone compositions that can be cured at low temperatures (for example, in Patent Document 4, etc. listed above), the cured material has low resistance to yellowing, making it difficult to use in applications requiring transparency. However, the cured product of the present invention has the advantage of being suitable for optical material applications, including optical semiconductor sealing agents, because it can be cured quickly at low temperatures if necessary, yet has excellent resistance to yellowing and maintains high transparency even when used under severe conditions. The composition of the present invention is also suitable for use in applications where a base material with poor heat resistance is sealed using a transparent cured product.

### [Use of Composition]

The curable hot-melt silicone composition of the present invention has hot-melt properties, excellent workability and curability while melted (hot-melted), and excellent coloring resistance of a resulting cured product obtained by curing the present composition at high temperature. Therefore, the composition is usefully used for sealing agents for light emitting/optical devices, optical reflective materials and other semiconductor members, and optical semiconductors having the cured product. Furthermore, since the cured product has superior mechanical properties, the cured product is suitable as: a sealing agent for semiconductors; a sealing agent for power semiconductors such as SiC, GaN, or the like; and as an adhesive, potting agent, protective agent, and coating agent for electrical and electronic applications. The curable hot-melt silicone composition of the present invention in sheet form is also suitable as a material for sealing and adhering large-area substrates using press molding, compression molding, a vacuum laminator, or the like. In particular, the composition is preferably used as a sealing agent for semiconductors using an overmold molding method at the time of molding. Furthermore, a sheet of this composition can be used as a curable film adhesive or as a buffer layer for stress between two substrates with different coefficients of linear expansion.

In addition, the curable hot-melt silicone composition of the present invention, and particularly the curable hot-melt silicone composition in sheet form, can be used for large-area sealing of semiconductor substrates (including wafers). Furthermore, a sheet formed from the curable hot-melt silicone composition of the present invention can be used for die attach films, sealing a flexible device, stress relief layers for bonding two different base materials, and the like. In other words, the curable silicone composition of the present invention may be a sealing agent for single-sided sealing or for double-sided sealing along with adhesion between two base materials, and have preferred properties suitable for these applications.

### [Use of Cured Product]

Applications for cured products obtained by curing a curable silicone composition of the present invention are not particularly limited. A composition of the present invention has hot-melt properties and excellent curability, moldability and mechanical properties, and cured products thereof have excellent yellowing resistance and can maintain high transparency. Therefore, the cured product obtained by curing the present composition can be suitably used as a member for a semiconductor device, and can be suitably used as a sealing agent for a semiconductor element, an IC chip or the like, and as an adhesive/bonding member of a conductor device.

Although semiconductor devices provided with a member made of a cured product obtained by curing a curable silicone composition of the present invention are not particularly limited, compositions of the present invention are especially suitable for applications that require light transmission to form optically transparent cured products. For example, it is preferably a light-emitting semiconductor device, which is a light-emitting/optical device, an optical member for a display, a solar panel member, and particularly a sealing agent or adhesive material used in these devices and the like. Furthermore, cured materials of the present invention have excellent resistance to yellowing (discoloration) when exposed to high temperatures or ultraviolet light, making it more suitable for use as a sealing agent or adhesive material in electronic materials where transparency and light/heat resistance are important.

### [Method for Sealing Semiconductor Device or Optical Semiconductor Device]

A curable hot-melt silicone composition of the present invention can be suitably used in sealing methods for semiconductors or optical semiconductor devices, including the following steps:
Step (E-1): adhering a curable hot-melt silicone composition of the present invention to some or all of a base material that is a semiconductor device, an optical semiconductor device, or a precursor thereof; and
Step (E-2): curing the uncured curable hot-melt silicone composition at room temperature or by heating after optional irradiation with a high energy beam.

As a step prior to (E-1), the curable hot-melt silicone composition of the present invention can be made to flow by heating to fill the unevenness and voids in the base material that is a semiconductor device, an optical semiconductor device, or precursor thereof, thereby enabling sealing of the semiconductor or optical semiconductor device with a cured product having excellent gap-filling properties between base materials.

### EXAMPLES

Hereinafter, the present invention is described in detail with reference to the examples and comparative examples, but the present invention is not limited to the following examples. In addition, due to the nature of the semi-cured product according to the present invention, the high energy beam irradiation is not performed at the same time during heat curing.

### (Measurement of Molecular Weight of Organopolysiloxane Component)

Weight average molecular weight (Mw) and number average molecular weight (Mn) of organopolysiloxane components such as the organopolysiloxane resin were determined using Waters gel permeation chromatography (GPC) with tetrahydrofuran (toluene) as the solvent and standard polystyrene conversion.

### Synthesis Example 1

In a 1000-mL four-neck flask, 333.0 g of a 60% xylene solution of MQ resin represented by the following average formula:

(Me₃SiSiO_{1/2})_{40.81}(Me₂ViSiO_{1/2})_{6.46}(SiO₂)_{52.73}

(vinyl content: 2% by mass, hereinafter referred to as the Vi-MQ resin) was mixed with 200.0 g of a polydimethylsiloxane having silanol groups at both ends and a viscosity of 12,500 mPa·s, and 133.0 g of toluene. To the resulting mixture was added 5 g of 30% aqueous ammonia, and the mixture was stirred at 40° C. for eight hours. Then, toluene was refluxed at 120° C. to distill off ammonia and water. The resulting reaction mixture was cooled to room temperature and admixed with 26.3 g of 3-(1,1,3,3-tetramethyldisiloxanyl) propyl methacrylate and 0.1 g of 4-methoxyphenol. To this mixture was added 2 ppm of a toluene solution of platinum/1,3-divinyltetramethyldisiloxane complex in terms of the mass of the platinum, the mixture was stirred for four hours while the temperature was adjusted to 40° C. to 50° C., and consumption of the SiH was confirmed by IR spectroscopy. As a result, 692 g of a methacryl-functional organopolysiloxane resin solution represented by the formula below was obtained.

(Me₃SiO_{1/2})_{20.36}(Me₂ViSiO_{1/2})_{0.90}(Me₂ViR^{A}SiO_{1/2})_{2.19}(Me₂SiO)_{50.05}(SiO₂)_{26.50}

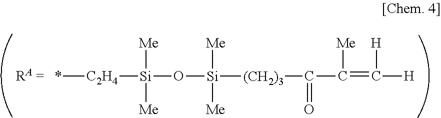

### Synthesis Example 2

In a 1,000-mL four-necked flask, 333.0 g of a 60% xylene solution of the above Vi-MQ resin (vinyl content of 2% by mass), 200.0 g of a silanol-capped polydimethylsiloxane with a viscosity of 2,300 mPa·s, and 133.0 g of toluene were added and mixed together. To the resulting mixture was added 5 g of 30% aqueous ammonia, and the mixture was stirred at 40° C. for eight hours. Then, toluene was refluxed at 120° C. to distill off ammonia and water. The resulting reaction mixture was cooled to room temperature and admixed with 26.3 g of 3-(1,1,3,3-tetramethyldisiloxanyl) propyl methacrylate and 0.1 g of 4-methoxyphenol. To this mixture was added 2 ppm of a toluene solution of platinum/1,3-divinyltetramethyldisiloxane complex in terms of the mass of the platinum, the mixture was stirred for four hours while the temperature was adjusted to 40° C. to 50° C., and consumption of the SiH was confirmed by IR spectroscopy. As a result, 692 g of a methacryl-functional organopolysiloxane resin solution represented by the formula below was obtained.

(Me₃SiO_{1/2})_{20.24}(Me₂ViSiO_{1/2})_{0.88}(Me₂ViR^{A}SiO_{1/2})_{2.16}(Me₂SiO)_{50.46}(SiO₂)_{26.25}

(where R^{A} is the monovalent substituent described in Synthesis Example 1)

### Synthesis Example 3

In a 1000-mL four-neck flask, 220.0 g of a 60% xylene solution of MQ resin represented by the following average formula:

(Me₃SiO_{1/2})_{45.0}(SiO₂)_{55.0}

was added to and mixed with 100.0 g of a silanol-capped polydimethylsiloxane having a viscosity of 12, 500mPa·s and 88.0 g of toluene. To the resulting mixture was added 30% ammonium hydroxide (5 g), and the mixture was stirred at 80° C. for 7 hours. Nitrogen gas was then blown into the flask at 120° C. to distill off ammonia and water. After cooling the mixture to 60° C., 15.0 g of hexamethyldisilazane and 0.3 g of trifluoroacetic acid were added to the mixture and reacted at the same temperature for 3 hours. Excess hexamethyldisilazane was distilled off at 120° C. After the reaction mixture was cooled to room temperature, inorganic salts were filtered out. To the resulting mixture were added 26.0 g of 3-(1,1,3,3-tetramethyldisiloxanyl) propyl methacrylate and 0.1 g of 4-methoxyphenol. To this mixture was added 2 ppm of a toluene solution of platinum/1,3-divinyltetramethyldisiloxane complex in terms of the mass of the platinum, the mixture was stirred for four hours while the temperature was adjusted to 40° C. to 50° C., and consumption of the SiH was confirmed by IR spectroscopy. As a result, 555 g of a methacryl-functional organopolysiloxane resin solution represented by the formula below was obtained.

(Me₃SiO_{1/2})_{33.33}(Me₂ViSiO_{1/2})_{0.65}(Me₂ViR^{A}SiO_{1/2})_{1.52}(Me₂SiO)_{26.2}(SiO₂)_{38.26}

(where R^{A} is a monovalent substituent represented by Formula I described above)

### Synthesis Example 4

To a 1000-mL four-necked flask, 166.7 g of a 60% xylene solution of Vi-MQ resin, 44.7 g of dimethylhydrogen siloxy-capped polydimethylsiloxane (0.01 mass % hydrogen content), and 30.0 g of toluene were added and mixed together. To this mixture, 2 ppm of a toluene solution of platinum/1,3-divinyltetramethyldisiloxane complex in terms of the mass of platinum was added, and the mixture was stirred at 90° C. for 3 hours. After the consumption of SiH was confirmed by IR spectroscopy, the resulting reaction mixture was cooled to room temperature, 18.2 g of 3-(1,1,3,3-tetramethyldisiloxanyl)propyl-methacrylate and 0.1 g of 4-methoxyphenol were added, and the mixture was stirred for four hours while adjusting the temperature to 40° C. to 50° C. The consumption of SiH was then confirmed again by IR spectroscopy. As a result, 259.8 g of methacryl-functional organopolysiloxane resin solution represented by the formula below was obtained.

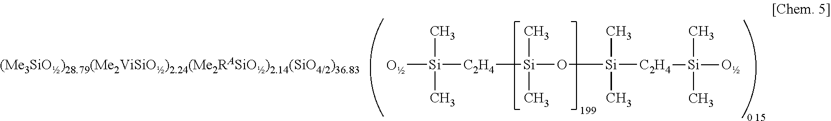

(where R^{A} is the monovalent substituent described in Synthesis Example 1)
A1: Organopolysiloxane shown in Synthesis Example (1)
A2: Organopolysiloxane shown in Synthesis Example (2)
A3: Organopolysiloxane shown in Synthesis Example (3)
B1: 2,4,6-trimethylbenzoyldiphenylphosphine oxide (product name Omnirad TPO, manufactured by IGM Resins)
B2: 2-hydroxy-2-methylpropiophenone (manufactured by Tokyo Chemical Industry Co., Ltd.)
C1: Organopolysiloxane resin having a weight average molecular weight (Mw) of 19,000 g/mol as measured by GPC using toluene as a solvent and having average composition of M_{0.52}M^{RA}_{0.01}Q_{0.47}, the resin consisting of a siloxane unit represented by (CH₃)₃SiO_{1/2} (M unit), a siloxane unit represented by R^{A}(CH₃)₂SiO_{1/2} (M^{RA} unit, where R^{A} is a monovalent substituent as described in Synthesis Example 1), and a siloxane unit represented by SiO_{4/2} (Q unit)
D1: Organopolysiloxane resin having a weight average molecular weight (Mw) of 18,000 g/mol as measured by GPC using toluene as the solvent and an average composition represented by M_{0.49}Q_{0.51}, the resin consisting of a siloxane unit represented by (CH₃)₃SiO_{1/2} (M unit) and a siloxane unit represented by SiO_{4/2} (Q unit)
D2: Organopolysiloxane resin (vinyl content: 1.90 mass %) having a weight average molecular weight (Mw) of 18,500 g/mol as measured by GPC using toluene as the solvent and an average composition of M_{0.42}M^{Vi}_{0.06}Q_{0.52}, the resin consisting of a siloxane unit represented by (CH₃)₃SiO_{1/2} (M unit), (CH₂═CH)(CH₃)₂SiO_{1/2} (M^{Vi} units), and SiO_{4/2} (Q units)
E1: Vinyl-capped raw polydimethylsiloxane rubber (ends/side chains) with a plasticity of 120 (vinyl content: 0.84 mass %)
E2: Trimethylsiloxy-capped polydimethylsiloxane with a plasticity of 170
E3: Dimethylvinylsiloxy-capped dimethylpolysiloxane with a viscosity of 39,000 mPa·s (vinyl group content: 0.09% by mass)
F1: Toluene

### Examples 1 to 7, Comparative Examples 1 to 3

Examples of the present invention and comparative examples are described hereinafter.

### [Preparation of Active Energy Ray Curable Reactive Silicone Compositions]

A toluene solution was prepared with each of the ingredients shown in Table 1 to achieve a 70% solid concentration of the compositions shown in each of the examples (Examples 1-7) and Comparative Example 1. Note that all percentages in Table 1 refer to mass %.

### Comparative Example 2

A toluene solution was prepared with a solid concentration of 70% of a composition consisting of 42 parts by mass of component D1, 23 parts by mass of component D2, 30 parts by mass of component E3, 3 parts by mass of an organohydrogen polysiloxane represented by the average structural formula below:

(Me₂HSiO_{1/2})_{0.3}(PhSiO_{3/2})_{0.7}

and 0.0020 parts by mass of a (methylcyclopentadienyl) trimethylplatinum complex.

### Comparative Example 3

A toluene solution was prepared with a solid concentration of 70% of a composition consisting of 0.1 parts by mass of component B, 38.9 parts by mass of component D1, 20.9 parts by mass of component D2, 27.6 parts by mass of component E2, and 12.5 parts by mass of an organohydrogen polysiloxane represented by the formula below:

Me₃SiO(Me₂SiO)₂₉[Me(HSC₃H₆)SiO]₃SiMe₃

### [Preparation of Active Energy Beam Curable Hot Melt Silicone Composition Film]

The solutions above were coated onto a release-treated PET film (NIPPA Co., Ltd: product name FSC-6) so that the thickness after heat drying was 200 um, and dried at 100° C. for 10 minutes. After cooling to room temperature, the release treated surface of the PET film was covered with the composition to produce an active energy beam cured hot-melt silicone film laminate at room temperature.

### [Softening Properties of the Uncured Film]

The uncured film cut to 8 mm diameter was attached to a measuring tool of the same diameter. The complex viscosity was measured when the sample had been heated from 25° C. to 80° C. at a rate of 3° C./min using a MCR302 manufactured by Anton Pearl Co., Ltd., and the complex viscosities at 25° C. and 80° C. were recorded. The results are shown in Table 1.

### [Preparation of Test Piece for Evaluating Optical Characteristics]

The PET film was peeled off from the hot-melt film laminate, and the laminate was sandwiched between two sheets of non-alkali glass (length 75 mm×width 50 mm×thickness 1.1 mm, Eagle XG manufactured by Corning Incorporated) so as not to allow air bubbles to enter. A test piece was then obtained by curing the hot-melt layer by irradiating the laminate with UV light at a 405 nm wavelength using a UV-LED UV irradiation device (manufactured by JATEC Co., Ltd) so that the UV irradiation dose (luminance was 4,000 mJ/cm² as the integrated luminous intensity. The presence of haze (=turbidity) and the b* value were recorded using CM-5 (Konica Minolta, Inc.). In addition, in order to evaluate the resistance of the cured product to yellowing, the b* values were also recorded for Example 1, Example 3, Comparative Example 2, and Comparative Example 3 after aging the same test pieces at 150° C., 85° C./85% relative humidity, and 500 hours in a QUV device. The results for the presence or absence of curing, the presence or absence of turbidity, and the b* value of each test example are shown in Tables 1 to 3.

### TABLE 1: Compositions of Examples 1 to 7 and Comparative Example 1, Hot-Melt Properties, Ultraviolet Curability, etc.

TABLE 1

| | | | | | | | | Comparative |
|---|---|---|---|---|---|---|---|---|
| Component | Example 1 | Example 2 | Example 3 | Example 4 | Example 5 | Example 6 | Example 7 | Example 1 |
| A1 | | 60 | 60 | 60 | | 55 | | |
| A2 | | | | | 59.5 | | | |
| A3 | 100 | | | | | | | |
| A4 | | | | | | | 100 | |
| B1 | 1 | 1 | 1 | 1 | 1 | | | 1 |
| B2 | | | | | | 1 | 1 | |
| C1 | | | 7.5 | | | | | 30 |
| D1 | | 40 | 32.5 | 30 | 40.5 | 35 | | 40 |
| D2 | | | | 10 | | | | |
| E1 | | | | | | 10 | | |
| E2 | | | | | | | | 30 |
| Complex Viscosity | 380000 | 89000 | 101300 | 63380 | 147780 | 10894 | 39454 | 20556 |
| at 25° C. (Pa · s) | | | | | | | | |
| Complex Viscosity | 6200 | 920 | 1290 | 680 | 1995 | 345 | 265 | 9919 |
| at 80° C. (Pa · s) | | | | | | | | |
| UV Curability | ∘ | ∘ | ∘ | ∘ | ∘ | ∘ | ∘ | x |
| (Cured ∘; Uncured x) | | | | | | | | |
| Appearance After | ∘ | ∘ | ∘ | ∘ | ∘ | ∘ | ∘ | x |
| UV Irradiation | | | | | | | | |
| (Transparent ∘; Turbid x) | | | | | | | | |

### TABLE 2: Ultraviolet Curability and Turbidity After Irradiation of Comparative Examples 1 to 3

TABLE 2

| | Comparative | Comparative | Comparative |
|---|---|---|---|
| | Example 1 | Example 2 | Example 3 |
| UV-Curability (Cured ∘; | x | x | ∘ |
| Uncured x) | | | |
| Appearance After UV | x | ∘ | ∘ |
| Irradiation (Transparent ∘; | | | |
| Turbid x) | | | |

### TABLE 3: b* Values (Yellowing) of Cured Test Pieces of the Examples and Comparative Examples

TABLE 3

| | Example | Example | Comparative | Comparative |
|---|---|---|---|---|
| Component | 1 | 3 | Example 2 | Example 3 |
| b* Before Aging | 0.2 | 0.0 | 0.1 | 0.1 |
| b* After 500 | 0.1 | 0.1 | 0.0 | 7.1 |
| Hours at 150° C. | | | | |
| b* After 500 Hours | 0.6 | 0.4 | 0.1 | 0.1 |
| at 85° C. and 85% | | | | |
| RH | | | | |
| QUV, b* After 500 | 2.0 | 0.9 | 0.1 | 2.7 |
| Hours | | | | |

As shown in Tables 1 and 2, the compositions containing an organopolysiloxane having a resin-linear structure of the present invention in Examples 1 to 7 were non-fluid at room temperature, capable of achieving low viscosity (hot-melt properties) suitable for sealing at 80° C., and provided cured products exhibiting good curing characteristics at room temperature and excellent transparency. Also, the resulting cured products (=test pieces of the examples) had high yellowing resistance as compared with the thiol-ene curing system composition that can be rapidly cured at room temperature shown in Comparative Example 3. Based on these characteristics, the curable hot-melt silicone compositions of the present invention are expected to have excellent sealing performance at 80° C., be curable at room temperature by irradiation with high energy beams, and produce cured products with excellent appearance stability and transparency when used in manufacturing processes such as those for display devices or electronic devices containing base materials that are unstable at high temperature. Meanwhile, as shown in Table 2, when a siloxane without a resin-linear structure was used as in Comparative Example 1, the curability was insufficient and the composition was not suitable for sealing. In addition, as shown in Tables 2 and 3, the composition in Comparative Example 2 has high yellowing resistance, but cannot be rapidly cured at room temperature, and thus may only be used in limited applications.

1. A curable hot-melt silicone composition comprising:
(A) 100 parts by mass of a resin-linear structure-containing organopolysiloxane block copolymer having: a resinous organosiloxane block X containing a siloxane unit (M^{RA} unit) represented by R^{A}ₐR^{B}₍₃₋ₐ₎SiO_{1/2} where R_{A} is a silicon atom-bound functional group containing acrylic or methacrylic groups, R^{B} is a monovalent organic group excluding R^{A}, and a is a number in the range 1 to 3, and a siloxane unit (Q unit) represented by SiO_{4/2} and having an acrylic group or methacrylic group, a chain organosiloxane block Y having a siloxane unit represented by {R^{C}₂SiO_{2/2}}_{β} where R^{C} is a monovalent organic group and β is 2 or more, and having at least two silicon atom-bound functional groups (R^{A}) above in the molecule; and
(B) 0.1 to 10 parts by mass of a radical polymerization initiator.

2. The curable hot-melt silicone composition according to claim 1, wherein component (A) is a resin-linear structure-containing organopolysiloxane block copolymer with a structure linked by a siloxane or silalkylene bond between silicon atoms comprising resin-like organosiloxane block X and chain organosiloxane block Y.

3. The curable hot-melt silicone composition according to claim 1, wherein component (A) contains a resinous organosiloxane block X having a siloxane unit (M unit) represented by R^{B}₃SiO_{1/2} where R^{B} is a monovalent organic group excluding R^{A} above, an M^{RA} unit and a Q unit, and the sum of the amount of substance of the M unit and M^{RA} unit per mole of Q unit is in the range of 0.5 to 2.0 moles.

4. The curable hot-melt silicone composition according to claim 1, wherein component (A) comprises a resinous organosiloxane block X and a chain organosiloxane block Y having a siloxane unit represented by {R^{C}₂SiO_{2/2}}_{β1} where R^{C} is a monovalent organic group and β1 is a number in the range 5 to 5000, block X and block Y being connected by siloxane bonds between silicon atoms.

5. The curable hot-melt silicone composition according to claim 1, wherein component (A) comprises a resinous organosiloxane block X in which the amount of substance of the M^{RA} unit per mole of Q unit is in the range of 0.02 to 0.50 moles.

6. The curable hot-melt silicone composition according to claim 1, wherein the silicon atom-bonded functional group R^{A} in component (A) is a functional group represented by the following general formula (1): 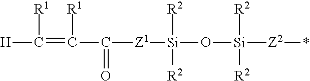
where each R¹ independently represents a hydrogen atom, a methyl group, or a phenyl group, and each R² each independently represents an alkyl group or an aryl group. Z¹ represents —O(CH₂)ₘ— where m is a number in the range of 0 to 3, Z² represents a divalent organic group expressed by —CₙH₂ₙ— where n is a number in the range of 2 to 10, bonded to a silicon atom constituting the main chain of the polysiloxane at *.

7. The curable hot-melt silicone composition according to claim 1, wherein at least some of component (B) is a photo-radical polymerization initiator (B1) and is photo-curable by irradiation with high energy beams.

8. The curable hot-melt silicone composition according to claim 1, further comprising:
(C) 0.1 to 50 parts by mass of an organopolysiloxane resin containing in the molecule an M unit represented by R^{B}₃SiO_{1/2} and R^{A}ₐR^{B}₍₃₋ₐ₎SiO_{1/2} where a represents an integer from 1 to 3 and each R^{B} independently represents a monovalent organic group excluding R_{A} and a Q unit, the ratio of the amount of substance of M units to Q units being in a range of 0.5 to 2.0.

9. The curable hot-melt silicone composition according to claim 1, further comprising:
(D) 0.1 to 200 mass parts of an organopolysiloxane resin containing an M unit represented by R^{B}₃SiO_{1/2} where each R independently represents an monovalent organic group except R_{A} and a Q unit, the ratio of M units to Q units being in the range of 0.5 to 2.0.

10. The curable hot-melt silicone composition according to claim 1, comprising:
(E) a polydimethylsiloxane that may optionally have an alkenyl group; and
(F) one or more organic solvents.

11. The curable hot-melt silicone composition according to claim 1, wherein the complex viscosity at 80° C. of the composition, prior to cure, is less than 10,000 Pa·s.

12. The curable hot-melt silicone composition according to claim 1, molded into a sheet or film.

13. A releasable laminate having:
a sheet or film of the curable hot-melt silicone composition according to claim 12; and
a sheet or film-like base material attached to one or both sides of the sheet or film of curable hot-melt silicone composition with a release surface opposite the sheet or film of curable hot-melt silicone composition, the sheet or film of curable hot-melt silicone composition being removable from the sheet or film-like base material with a release surface.

14. A cured product obtained by curing the curable hot-melt silicone composition according to claim 1.

15. A cured product obtained by curing the light-curable hot-melt silicone composition according to claim 7 by irradiation with a high energy beam.

16. A semiconductor device or an optical semiconductor device, comprising the cured product according to claim 14.

17. A method for producing a sheet or film of the curable hot-melt silicone composition, the method comprising:
Step (I): applying the curable hot-melt silicone composition according to claim 1 on a base material; and
Step (II): heating and drying the composition applied in Step (I) to obtain a composition formed into the shape of a sheet or film.

18. A method for sealing a semiconductor device or optical semiconductor device, the method comprising:
Step (E-I): adhering the curable hot-melt silicone composition according to claim 1 to some or all of a base material that is a semiconductor device, an optical semiconductor device, or a precursor thereof, with the composition in an uncured state; and
Step (E-2): curing the uncured curable hot-melt silicone composition at room temperature or by heating, optionally after irradiation with a high-energy beam.
